(19) United States
(12) Patent Application Publication
(10) Pub. No.: US 2026/0217900 A1
(43) Pub. Date: Jul. 30, 2026

(54) POLYURETHANE RESIN FOR POLISHING PADS, AND POLISHING PAD

(71) Applicant: SANYO CHEMICAL INDUSTRIES, LTD., Kyoto (JP)

(72) Inventors: Atsushi WAKATSUKI, Kyoto (JP); Kenta KUCHIDA, Kyoto (JP); Miki IIMURO, Kyoto (JP); Masafumi SAWADA, Kyoto (JP)

(73) Assignee: SANYO CHEMICAL INDUSTRIES, LTD., Kyoto (JP)

(21) Appl. No.: 19/146,058

(22) PCT Filed: Jan. 10, 2024
(86) PCT No.: PCT/JP2024/000285

§ 371 Date: Jul. 7, 2025

(30) Foreign Application Priority Data
Jan. 12, 2023 (JP) 2023-002979

(51) Int. Cl. C08G 18/66; B24B 37/24; C08G 18/32; C08G 18/34; C08G 18/38; C08G 18/40; C08G 18/42; C08G 18/44; C08G 18/48; C08G 18/75; C08G 18/76

(52) U.S. Cl. CPC C08G 18/6659; B24B 37/24; C08G 18/3206; C08G 18/348; C08G 18/3855; C08G 18/4018; C08G 18/4238; C08G 18/44; C08G 18/4833; C08G 18/4854; C08G 18/664; C08G 18/6692; C08G 18/758; C08G 18/7671

(57) ABSTRACT

Provided is a polyurethane resin (U) for a polishing pad, containing, as constituent monomers: at least one polyol (a) selected from the group consisting of a polyether polyol (a11), a polyester polyol (a12), and a polycarbonate polyol (a13); a polyisocyanate (b); and a compound (c) having an ionic group and two active hydrogen atoms, the polyurethane resin (U) for a polishing pad containing, among constituent components thereof, an active hydrogen atom-containing component (A′) having an HLB of 8.0 or higher in an amount of 80 to 100% by weight based on a weight of an active hydrogen atom-containing component (A).

### TECHNICAL FIELD

The present invention relates to a polyurethane resin for a polishing pad and a polishing pad.

### BACKGROUND ART

A chemical mechanical polishing (CMP) process is used to polish semiconductors and wafers. In the CMP process, a workpiece to be polished is polished using a polishing slurry containing fine particles of alumina, silica, or the like on a polishing pad, thereby flattening the surface of the workpiece and removing unnecessary portions.

As a polishing pad, a polyurethane resin containing polytetramethylene glycol as a polyol component has been proposed (e.g., Patent Literature 1).

### CITATION LIST

### Patent Literature

Patent Literature 1: JP 2019-116616 A

### SUMMARY OF INVENTION

### Technical Problem

However, even the technique of Patent Literature 1 does not sufficiently reduce scratches on the surface of a workpiece to be polished, and there is a need for improvement. The present invention aims to provide a polyurethane resin for a polishing pad that can provide a polishing pad excellent in durability and capable of reducing scratches on a workpiece to be polished.

### Solution to Problem

As a result of studies to achieve the above object, the present inventors have reached the present invention. Specifically, the present invention relates to a polyurethane resin (U) for a polishing pad, containing, as constituent monomers: at least one polyol (a) selected from the group consisting of a polyether polyol (a11), a polyester polyol (a12), and a polycarbonate polyol (a13); a polyisocyanate (b); and a compound (c) having an ionic group and two active hydrogen atoms, and the polyurethane resin (U) for a polishing pad contains, among constituent components thereof, an active hydrogen atom-containing component (A′) having an HLB of 8.0 or higher in an amount of 80 to 100% by weight based on a weight of an active hydrogen atom-containing component (A). The present invention also relates to a polishing pad (Uα) containing the polyurethane resin (U) for a polishing pad of the present invention.

### Advantageous Effects of Invention

The present invention can provide a polyurethane resin for a polishing pad that can provide a polishing pad excellent in durability and capable of reducing scratches on a workpiece to be polished.

### DESCRIPTION OF EMBODIMENTS

The polyurethane resin (U) for a polishing pad of the present invention contains, as constituent monomers: at least one polyol (a) selected from the group consisting of a polyether polyol (a11), a polyester polyol (a12), and a polycarbonate polyol (a13); a polyisocyanate (b); and a compound (c) having an ionic group and two active hydrogen atoms, and the polyurethane resin (U) for a polishing pad contains, among constituent components thereof, an active hydrogen atom-containing component (A′) having an HLB of 8.0 or higher in an amount of 80 to 100% by weight based on a weight of an active hydrogen atom-containing component (A).

<Polyol (a)>

The polyol (a) in the present invention is selected from the group consisting of a polyether polyol (a11), a polyester polyol (a12), and a polycarbonate polyol (a13).

The polyol (a) preferably has a number average molecular weight (hereinafter abbreviated as Mn) of 300 or more.

From the viewpoint of the retention of the polishing slurry, a polyether polyol (a11) and a polyester polyol (a12) are preferred as the polyol (a), with a polyester polyol (a12) being more preferred.

These polyols (a) may be used alone or in combination of two or more thereof.

<Polyether Polyol (a11)>

Examples of the polyether polyol (a11) in the present invention include aliphatic polyether polyols and aromatic polyether polyols.

Examples of the aliphatic polyether polyols include polyoxyethylene polyols (e.g., polyethylene glycol), polyoxypropylene polyols (e.g., polypropylene glycol), polyoxyethylene/polyoxypropylene polyols, and polytetramethylene ether glycol.

Examples of the aromatic polyether polyols include: polyols having a bisphenol skeleton, including adducts of bisphenol A with ethylene oxide (hereinafter abbreviated as EO) (e.g., an adduct of bisphenol A with 4 mol of EO, an adduct of bisphenol A with 6 mol of EO, an adduct of bisphenol A with 8 mol of EO, an adduct of bisphenol A with 10 mol of EO, and an adduct of bisphenol A with 20 mol of EO) and adducts of bisphenol A with propylene oxide (hereinafter abbreviated as PO) (e.g., an adduct of bisphenol A with 3 mol of PO and an adduct of bisphenol A with 5 mol of PO); and adducts of resorcin with EO or PO.

Of the polyether polyols (a11), from the viewpoint of ease of adjusting the HLB and the like, aliphatic polyether polyols are preferred.

The polyether polyol (a11) preferably has an Mn of 300 to 5,000, more preferably 300 to 3,000, particularly preferably 300 to 2,500, from the viewpoint of the balance between ease of adjusting the HLB and the durability of the polishing pad.

<Polyester Polyol (a12)>

Examples of the polyester polyol (a12) in the present invention include condensation-type polyester polyols, polylactone polyols, and castor oil-based polyols.

Examples of the condensation-type polyester polyols include polyester polyols of low molecular weight polyhydric alcohols (Mn: less than 300) and C2-C10 polycarboxylic acids or ester-forming derivatives of the C2-C10 polycarboxylic acids.

The low molecular weight polyhydric alcohols may be aliphatic polyhydric alcohols having 2 to 8 or more hydroxy groups and having an Mn of less than 300 or adducts having an Mn of less than 300, having 2 to 8 or more hydroxy groups and obtainable by adding a small mole of alkylene oxide (e.g., EO, PO, 1,2-, 1,3-, 2,3-, or 1,4-butylene oxide, hereinafter abbreviated as AO) to phenolic compounds.

Of the low molecular weight polyhydric alcohols usable as the condensation-type polyester polyols, from the viewpoint of the balance between ease of adjusting the HLB and the durability of the polishing pad, ethylene glycol, propylene glycol, 1,4-butanediol, neopentyl glycol, 1,6-hexane glycol, an adduct of bisphenol A with a small mole of EO or PO, and combinations thereof are preferred, with ethylene glycol, propylene glycol, 1,4-butanediol, and combinations thereof being more preferred.

Examples of the C2-C10 polycarboxylic acids or their ester-forming derivatives usable as the condensation-type polyester polyols include aliphatic dicarboxylic acids (e.g., succinic acid, adipic acid, azelaic acid, sebacic acid, fumaric acid, and maleic acid), alicyclic dicarboxylic acids (e.g., dimer acid), aromatic dicarboxylic acids (e.g., terephthalic acid, isophthalic acid, and phthalic acid), polycarboxylic acids having three or more carboxyl groups (e.g., trimellitic acid and pyromellitic acid), anhydrides thereof (e.g., succinic anhydride, maleic anhydride, phthalic anhydride, and trimellitic anhydride), acid halides thereof (e.g., adipic acid dichloride), low molecular weight alkyl esters thereof (e.g., dimethyl succinate and dimethyl phthalate), and combinations thereof.

Of the C2-C10 polycarboxylic acids or their ester-forming derivatives described above, from the viewpoints of the durability of the polishing pad and ease of adjusting the HLB, aliphatic dicarboxylic acids are preferred, with adipic acid being more preferred.

Specific examples of the condensation-type polyester polyols include polyethylene adipate diol, polybutylene adipate diol, polyhexamethylene adipate diol, polyhexamethylene isophthalate diol, polyneopentyl adipate diol, polyethylene propylene adipate diol, polyethylene butylene adipate diol, polybutylene hexamethylene adipate diol, polydiethylene adipate diol, poly(polytetramethylene ether) adipate diol, poly(3-methylpentylene adipate) diol, polyethylene azelate diol, polyethylene sebacate diol, polybutylene azelate diol, polybutylene sebacate diol, and polyneopentyl terephthalate diol.

Examples of commercially available condensation-type polyester polyols include SANESTER 2610 (polyethylene adipate diol having an Mn of 1,000, available from Sanyo Chemical Industries, Ltd.), SANESTER 4620 (polytetramethylene adipate diol having an Mn of 2,000), and SANESTER 2620 (polyethylene adipate diol having an Mn of 2,000, available from Sanyo Chemical Industries, Ltd.).

The polylactone polyols are polyaddition products of the low molecular weight polyhydric alcohols with lactone. Examples of the lactone include C4-C12 lactones (e.g., γ-butyrolactone, γ-valerolactone, and ε-caprolactone).

Specific examples of the polylactone polyols include polycaprolactone diol, polyvalerolactone diol, and polycaprolactone triol.

The castor oil-based polyols include castor oil and modified castor oil modified with a polyol or AO. Modified castor oil can be produced by transesterification of castor oil with a polyol and/or by AO addition. Examples of the castor oil-based polyols include castor oil, trimethylolpropane-modified castor oil, pentaerythritol-modified castor oil, and an adduct of castor oil with EO (4 to 30 mol).

Of the polyester polyols (a12), from the viewpoints of the durability of the polishing pad and ease of adjusting the HLB, condensation-type polyester polyols are preferred, with polyethylene adipate diol, polybutylene adipate diol, and polyhexamethylene adipate diol being more preferred.

The polyester polyol (a12) preferably has an Mn of 300 to 10,000, more preferably 600 to 7,000, particularly preferably 1,000 to 4,000.

<Polycarbonate Polyol (a13)>

Examples of the polycarbonate polyol (a13) include polycarbonate polyols produced by condensation of the low molecular weight polyhydric alcohols described above with low molecular weight carbonate compounds (e.g., a dialkyl carbonate having a C1-C6 alkyl group, an alkylene carbonate having a C2-C6 alkylene group, and a diaryl carbonate having a C6-C9 aryl group) through a dealcoholization reaction. Two or more of the low molecular weight polyhydric alcohols may be used in combination, and two or more of the low molecular weight carbonate compounds may be used in combination.

Specific examples of the polycarbonate polyol (13a) include polyhexamethylene carbonate diol, polypentamethylene carbonate diol, polytetramethylene carbonate diol, and poly(tetramethylene/hexamethylene) carbonate diol (e.g., a diol obtained by condensation of 1,4-butanediol and 1,6-hexanediol with a dialkyl carbonate through a dealcoholization reaction).

Examples of commercially available polycarbonate polyols (a13) include NIPPOLLAN 980R (polyhexamethylene carbonate diol having an Mn of 2,000, available from Tosoh Corporation), KURARAY POLYOL C-3090 (poly(3-methyl-5-pentanediol/hexamethylene) carbonate diol having an Mn of 3,000), and T4672 (poly(tetramethylene/hexamethylene) carbonate diol having an Mn of 2,000, available from Asahi Kasei Corporation).

Of the polycarbonate polyols (a13), from the viewpoint of ease of adjusting the HLB, a polycarbonate diol obtained by condensation of 1,4-butanediol and 1,5-pentanediol or 1,6-hexanediol with a dialkyl carbonate through a dealcoholization reaction is preferred.

The polycarbonate polyol (a13) preferably has an Mn of 300 to 5,000, more preferably 300 to 3,000, particularly preferably 300 to 2,500, from the viewpoints of the durability of the polishing pad and ease of adjusting the HLB.

The Mn in the present invention can be measured by gel permeation chromatography, for example, under the following conditions.
Device: Waters Alliance 2695 (available from Waters Corporation)
Columns: “Guard column Super H-L (one column)”, “TSKgel SuperH2000 (one column), TSKgel SuperH3000 (one column), and TSKgel SuperH4000 (one column) (all available from Tosoh Corporation) connected together”
Sample solution: 0.25% by weight solution of a sample in tetrahydrofuran
Amount of solution injected: 10 μL
Flow rate: 0.6 mL/min
Measurement temperature: 40° C.
Detector: refractive index detector
Reference material: standard polyethylene glycol
   <Polyisocyanate (b)>

The polyisocyanate (b) in the present invention is a compound having two or more isocyanate groups, and examples thereof include C6-C20 (excluding the carbon atoms in the isocyanate groups, the same applies hereinafter) aromatic polyisocyanates (b1), C2-C18 aliphatic polyisocyanates (b2), C4-C15 alicyclic polyisocyanates (b3), and modified products (b4) of these polyisocyanates (b1) to (b3), all of which have two or more isocyanate groups.

These polyisocyanates (b) may be used alone or in combination of two or more thereof.

Examples of the C6-C20 aromatic polyisocyanates (b1) include 1,3- or 1,4-phenylene diisocyanate, 2,4- or 2,6-tolylene diisocyanate (TDI), 4,4′- or 2,4′-diphenylmethane diisocyanate (MDI), 1,5-naphthylene diisocyanate, 4,4′,4″-triphenylmethane triisocyanate, m- or p-isocyanatophenylsulfonyl isocyanate, crude MDI, m- or p-xylylene diisocyanate (XDI), and α,α,α′,α′-tetramethylxylylene diisocyanate (TMXDI).

Examples of the C2-C18 aliphatic polyisocyanates (b2) include ethylene diisocyanate, tetramethylene diisocyanate, hexamethylene diisocyanate (HDI), dodecamethylene diisocyanate, 2,2,4-trimethylhexamethylene diisocyanate, lysine diisocyanate, 4,4′-methylenebiscyclohexyl diisocyanate, and 2-isocyanatoethyl-2,6-diisocyanatohexanoate.

Examples of the C4-C15 alicyclic polyisocyanates (b3) include isophorone diisocyanate (IPDI), 4,4-dicyclohexylmethane diisocyanate (hydrogenated MDI, 4,4′-methylenebiscyclohexyl diisocyanate), cyclohexylene diisocyanate, methylcyclohexylene diisocyanate (hydrogenated TDI), bis(2-isocyanatoethyl)-4-cyclohexene-1,2-dicarboxylate, and 2,5- or 2,6-norbornane diisocyanate.

Examples of the modified products (b4) include modified products of the polyisocyanates (b1) to (b3) containing a urethane group, a carbodiimide group, an allophanate group, a urea group, a biuret group, a uretdione group, a uretimine group, an isocyanurate group, or an oxazolidone group [such as modified MDI (e.g., urethane-modified MDI, carbodiimide-modified MDI, and trihydrocarbyl phosphate-modified MDI), urethane-modified TDI, a biuret of HDI, an isocyanurate of HDI, and an isocyanurate of IPDI].

Of the polyisocyanates (b), from the viewpoint of durability, the C6-C20 aromatic polyisocyanates (b1) are preferred, with MDI being more preferred.

### <Compound (c) Having Ionic Group and Two Active Hydrogen Atoms>

The ionic group in the present invention is a general term for cationic groups such as cationic nitrogen atoms (e.g., >N⁺< and ═N⁺<) and anionic groups such as —SO₃⁻ and —COO⁻.

The active hydrogen atom refers to a hydrogen atom which is bonded to an atom such as an oxygen atom, a nitrogen atom, or a sulfur atom and is highly reactive with an isocyanate group. Examples of a group having such an active hydrogen atom (active hydrogen atom-containing group) include a hydroxy group, a primary amino group, a secondary amino group, and a thiol group.

The compound (c) having an ionic group and two active hydrogen atoms in the present invention preferably has a number average molecular weight (Mn) or chemical formula weight of less than 300. Examples thereof include a compound (c1) having an anionic group and active hydrogen atoms and a compound (c2) having a cationic group and active hydrogen atoms.

These compounds (c) may be used alone or in combination of two or more thereof.

The Mn or chemical formula weight of the compound (c2) is preferably less than 300.

The anionic group in the compound (c1) refers to an acid group or a neutralized acid anion group.

Examples of the compound (c1) include: C2-C10 compounds having a carboxyl group as an anionic group and an active hydrogen atom-containing group selected from a hydroxy group and an amino group [such as dialkylol alkanoic acids (e.g., dimethylolpropionic acid, 2,2-dimethylolbutanoic acid, 2,2-dimethylolheptanoic acid, and 2,2-dimethyloloctanoic acid), tartaric acid, and amino acids (e.g., glycine, alanine, and valine)]; C2-C16 compounds having a sulfonic acid group as an anionic group and hydroxy groups as active hydrogen atom-containing groups [such as 3-(2,3-dihydroxypropoxy)-1-propanesulfonic acid and sulfoisophthalic acid di(ethylene glycol) ester]; C2-C10 compounds having a sulfamic acid group as an anionic group and hydroxy groups as active hydrogen atom-containing groups [such as N,N-bis(2-hydroxyethyl) sulfamic acid; and salts obtained by neutralizing these compounds with a neutralizing agent.

Examples of the neutralizing agent used to neutralize the compound (c1) include ammonia, a C1-C20 amine compound, and an alkali metal hydroxide (e.g., sodium hydroxide, potassium hydroxide, and lithium hydroxide).

Examples of the compound (c2) include salts obtained by neutralizing compounds having a tertiary amino group as a cationic group and hydroxy groups as active hydrogen atom-containing groups with a neutralizing agent. Examples of the compounds include C1-C20 tertiary amino group-containing diols [such as N-alkyldialkanolamines (e.g., N-methyldiethanolamine, N-propyldiethanolamine, N-butyldiethanolamine, and N-methyldipropanolamine)], N,N-dialkylmonoalkanolamines (e.g., N,N-dimethylethanolamine), and trialkanolamines (e.g., triethanolamine).

Examples of the neutralizing agent used to neutralize the compound (c2) include C1-C10 monocarboxylic acids (e.g., formic acid, acetic acid, and propanoic acid), carbonic acid, dimethyl carbonate, dimethyl sulfate, methyl chloride, and benzyl chloride.

Of the compounds (c), from the viewpoint of the retention of the polishing slurry, the compound (c1) is preferred, with a dialkylol alkanoic acid and its salts being more preferred.

The polyurethane resin (U) for a polishing pad may optionally contain a chain extender (d) and a reaction terminator (e) as constituent monomers in addition to the polyol (a), the polyisocyanate (b), and the compound (c).

<Chain Extender (d)>

The chain extender (d) may be a compound having two or more active hydrogen atoms other than the above compounds. Examples thereof include water; C2-C8 aliphatic diols [such as linear aliphatic diols (e.g., ethylene glycol, diethylene glycol, 1,3-propanediol, 1,4-butanediol, 1,5-pentanediol, and 1,6-hexanediol) and diols having branched alkyl chains (e.g., 1,2-propanediol, neopentyl glycol, 3-methyl-1,5-pentanediol, 2,2-diethyl-1,3-propanediol, 1,2-, 1,3-, or 2,3-butanediol)]; dihydric alcohols having a C6-C10 alicyclic group [e.g., 1,4-bis(hydroxymethyl)cyclohexane and 2,2-bis(4-hydroxycyclohexyl)propane]; C8-C20 aromatic dihydric alcohols [e.g., m- or p-xylylene glycol, bis(hydroxyethyl)benzene, and bis(hydroxyethoxy)benzene]; adducts of bisphenols (e.g., bisphenol A, bisphenol S, and bisphenol F) with AO, adducts of dihydroxynaphthalene with AO, and bis(2-hydroxyethyl) terephthalate; C2-C10 diamines (e.g., ethylene diamine, propylene diamine, hexamethylene diamine, isophorone diamine, toluene diamine, and piperazine); C2-C10 polyalkylene polyamines (e.g., diethylene triamine and triethylene tetramine); hydrazine or a derivative thereof (dibasic acid dihydrazides such as adipic acid dihydrazide); C2-C30 polyepoxy compounds (e.g., 1,6-hexanediol diglycidyl ether and trimethylolpropane polyglycidyl ether); and C2-C10 aminoalcohols (e.g., monoethanolamine, diethanolamine, isopropanolamine, and 2-amino-2-methylpropanol).

The chain extender (d) preferably has an Mn or chemical formula weight of less than 300.

Of the chain extenders (d), C2-C8 aliphatic diols are preferred, with C2-C8 linear aliphatic diols being more preferred and ethylene glycol being particularly preferred.

<Reaction Terminator (e)>

Examples of the reaction terminator (e) include C1-C8 monoalcohols (e.g., methanol, ethanol, isopropanol, n-butanol, cellosolves, and carbitols) and C1-C10 monoamines (e.g., mono- or dialkylamines such as monomethylamine, monoethylamine, monobutylamine, dibutylamine, and monooctylamine).

### <Active Hydrogen Atom-Containing Component (A′) Having HLB of 8.0 or Higher>

The polyurethane resin (U) contains, among constituent components thereof, an active hydrogen atom-containing component (A) (hereinafter also referred to simply as a component (A)), and the component (A) may include the polyol (a), compound (c), chain extender (d), and reaction terminator (e) described above. In the present invention, of these components (A), a component having an HLB of 8.0 or higher corresponds to an active hydrogen atom-containing component (A′) having an HLB of 8.0 or higher (hereinafter also referred to simply as a component (A′)).

Among the component (A′), a polyether polyol (a11) and a polyester polyol (a12) each having a HLB of 8.0 or higher are preferable as the polyol (a) from the viewpoint of the retention of the polishing slurry, and a polyester polyol (a12) having an HLB of 8.0 or higher is more preferable.

Among the component (A′), a compound (c1) having an HLB of 8.0 or higher is preferable as the compound (c) from the viewpoint of the retention of the polishing slurry, and a compound having a carboxyl group and/or a sulfonic acid group as an anionic group is more preferable.

Among the component (A′), a C2-C8 aliphatic diol having an HLB of 8.0 or higher is preferable as the chain extender (d) from the viewpoint of the retention of the polishing slurry, and a C2-C8 linear aliphatic diol is more preferable.

Among the component (A′), a C1-C8 monoalcohol or a C1-C10 monoamine, each having an HLB of 8.0 or higher is preferable as the reaction terminator (e) from the viewpoint of the retention of the polishing slurry.

### <Polyurethane Resin (U) for Polishing Pad>

The polyurethane resin (U) for a polishing pad contains, among constituent components thereof, the active hydrogen atom-containing component (A′) having an HLB of 8.0 or higher in an amount of 80 to 100% by weight based on the weight of the active hydrogen atom-containing component (A). From the viewpoint of the retention of the polishing slurry, the amount is preferably 85 to 100% by weight. If the amount is less than 80% by weight, the retention of the polishing slurry deteriorates.

HLB (hydrophile-lipophile balance) is an index showing the balance between hydrophilicity and lipophilicity. The HLB value is known, for example, as a value calculated according to the Oda method described in “Introduction to Surfactants (Kaimen Kasseizai Nyumon)”, p. 212, Sanyo Chemical Industries, Ltd., 2007 (Takehiko Fujimoto), and is not a value calculated according to the Griffin method.

The HLB value of a compound can be calculated from the ratio between the organic value and the inorganic value of the compound using the following equation.

HLB=10×Inorganic value/Organic value

Regarding the organic value and the inorganic value for the HLB, the organic value is set to 20 per carbon atom, and the inorganic value is calculated using the values (the “numerical value” of the inorganic group or the “inorganic” value of the organic and inorganic group) shown in the table on p. 213 of the above-described “Introduction to Surfactants (Kaimen Kasseizai Nyumon)”. Examples of the calculation are described as follows:
—CH₃ group: organic value 20, inorganic value 0;
—CH₂— group: organic value 20, inorganic value 0;
═CH₂ group: organic value 20, inorganic value 1;
═CH— group: organic value 20, inorganic value 1;
benzene ring: organic value 120, inorganic value 15;
—O— group: inorganic value 20;
—COO—: organic value 20, inorganic value 60;
—OH group: inorganic value 100; and
—COOH group: organic value 20, inorganic value 150.

In addition, in the calculation of the HLB value in the present invention, the following organic value and inorganic value are used for the following components. COO⁻M⁺: organic value 20, inorganic value 400 (“M⁺” is a counter ion of “COO⁻” and represents a metal cation or ammonium cation)

### Si Atom: Organic Value 0, Inorganic Value 0

When a plurality of compounds are used as the polyurethane resin (U), the amount by weight of the component (A′) included in the component (A) is calculated based on the total weight of all compounds corresponding to the component (A) and the total weight of all compounds corresponding to the component (A′) contained in the constituent components of each polyurethane resin.

The polyurethane resin (U) preferably has an ionic group concentration (ionic group content of the polyurethane resin (U)) of 0.020 to 0.500 mol/kg, more preferably 0.025 to 0.450 mol/kg, particularly preferably 0.030 to 0.400 mol/kg, from the viewpoints of the retention and handling properties of the polishing slurry.

The ionic group concentration can be calculated by subjecting the polyurethane resin (U) to ¹H-NMR analysis and/or 13C-NMR analysis.

From the viewpoints of durability and handling properties, the polyurethane resin (U) preferably has an Mn of 1,000 to 20,000, more preferably 2,000 to 15,000, particularly preferably 3,000 to 10,000.

The polyurethane resin (U) preferably has a urethane group concentration of 1.0 to 6.0 mol/kg, more preferably 1.5 to 5.0 mol/kg, particularly preferably 2.0 to 4.5 mol/kg, from the viewpoints of durability and handling properties.

The urethane group concentration of the polyurethane resin (U) can be calculated from the nitrogen content determined by a nitrogen analyzer [ANTEK 7000 (Antek Instruments, Inc.)] and the ratio between urethane groups and urea groups determined by ¹H-NMR. The ¹H-NMR analysis is carried out according to the method described in “Structural study of polyurethane resins by NMR: Reports of the Takeda Research Laboratory (Takeda Kenkyusho Ho), 34 (2), pp. 224-323 (1975)”. Specifically, in the case where an aliphatic polyisocyanate (b2), an alicyclic polyisocyanate (b3), or a modified product thereof is used, the weight ratio between urea groups and urethane groups is calculated from the ratio between the integral of the urea-derived proton appearing near 6 ppm in the ¹H-NMR spectrum and the integral of the urethane-derived proton appearing near 7 ppm in the ¹H-NMR spectrum. Then, the urethane group concentration is calculated from the weight ratio and the nitrogen content. In the case where an aromatic polyisocyanate (b1) or a modified product thereof is used, the weight ratio between urea groups and urethane groups is calculated from the ratio between the integral of the urea-derived proton appearing near 8 ppm in the ¹H-NMR spectrum and the integral of the urethane-derived proton appearing near 9 ppm in the ¹H-NMR spectrum. Then, the urethane group concentration is calculated from the weight ratio and the nitrogen content.

The ionic group concentration, Mn, and urethane group concentration of the polyurethane resin (U) can be appropriately adjusted by selecting the types and weight ratio of the monomers constituting the polyurethane resin (U).

From the viewpoint of the durability of the polishing pad, the weight of the polyol (a) is preferably 35 to 75% by weight, more preferably 40 to 70% by weight, based on the total weight of the monomers constituting the polyurethane resin (U).

The monomers for the polyurethane resin (U) are preferably reacted in such a ratio that the equivalent ratio between isocyanate groups and active hydrogen atoms (isocyanate group/active hydrogen atom) in all the constituent monomers is 0.80 to 1.20.

The polyurethane resin (U) of the present invention can be produced, for example, by any of the following methods.
(1) A polyol (a), a polyisocyanate (b), a compound (c), an optional chain extender (d), and an optional reaction terminator (e) are reacted. The reaction may optionally be carried out in a solvent(s).
(2) A polyol (a), a polyisocyanate (b), a compound (c), and an optional chain extender (d) are reacted. The reaction may optionally be carried out in a solvent(s). Thereby, a NCO group-terminated prepolymer is obtained. Then, the NCO group-terminated prepolymer is reacted with a reaction terminator (e).

Of the methods (1) and (2), the method (2) is preferred from an industrial viewpoint.

Examples of the solvent(s) include ethyl acetate, N,N-dimethylformamide (DMF), and toluene.

The polyurethane resin (U) may optionally further contain additives such as an antioxidant (e.g., dibutylhydroxytoluene), a gelation inhibitor (e.g., benzoyl chloride), a discoloration inhibitor, a weathering stabilizer, a plasticizer, and a release agent. The amount of these additives used is usually 10% by weight or less, preferably 3% by weight or less, particularly preferably 1% by weight or less, based on the weight of the polyurethane resin (U).

### <Polishing Pad (Uα)>

The polishing pad (Uα) of the present invention contains the polyurethane resin (U) for a polishing pad of the present invention. Preferably, the polishing pad (Uα) is a molded article obtained by molding the polyurethane resin (U) for a polishing pad or a solution thereof by a known method. When the solution of the polyurethane resin (U) is molded, the weight of the polyurethane resin (U) based on the weight of the solution (the resin concentration of the solution) is preferably 10 to 60% by weight from the viewpoint of handling properties.

The molded article may be either a foam or a non-foam, and can be appropriately selected depending on the polishing applications.

The polyurethane resin (U) for a polishing pad and the polishing pad (Uα) of the present invention are excellent in retention of the polishing slurry, and are thus capable of reducing scratches on a workpiece to be polished. The polishing pad is also excellent in durability, and is thus suitable for various polishing applications, in particular, chemical mechanical polishing (CMP) applications.

For example, in chemical mechanical polishing (CMP), a workpiece to be polished (semiconductor or wafer) is polished using a polishing slurry containing fine particles of alumina, silica, or the like on a polishing pad, thereby flattening the surface and removing unnecessary portions.

The following matters are disclosed herein.

The disclosure (1) relates to a polyurethane resin (U) for a polishing pad, containing, as constituent monomers: at least one polyol (a) selected from the group consisting of a polyether polyol (a11), a polyester polyol (a12), and a polycarbonate polyol (a13); a polyisocyanate (b); and a compound (c) having an ionic group and two active hydrogen atoms, the polyurethane resin (U) for a polishing pad contains, among constituent components thereof, an active hydrogen atom-containing component (A′) having an HLB of 8.0 or higher in an amount of 80 to 100% by weight based on a weight of an active hydrogen atom-containing component (A).

The disclosure (2) relates to the polyurethane resin (U) for a polishing pad of the disclosure (1), wherein the polyurethane resin (U) has an ionic group concentration of 0.020 to 0.500 mol/kg.

The disclosure (3) relates to a polishing pad (Uα) containing the polyurethane resin (U) for a polishing pad of the disclosure (1) or (2).

### EXAMPLES

The present invention is further described below with reference to examples, but the present invention is not limited thereto.

### Example 1

A four-neck flask was charged with 17,880 g of a solvent (s-1) [N,N-dimethylformamide], 3,328 g of a polyester polyol (a12-1) [polyethylene adipate diol, Mn: 2,000, trade name: SANESTER 2620], 284 g of a chain extender (d-1) [ethylene glycol], 287 g of a compound (c-1) [2,2-dimethylolpropionic acid], 3.3 g of dibutyl hydroxytoluene, 0.72 g of benzoyl chloride, and 2,101 g of a polyisocyanate (b-1) [4,4′-diphenylmethane diisocyanate (4,4′-MDI)]. The contents were reacted for 10 hours at 60° C. under a dry nitrogen atmosphere. Then, 120 g of a reaction terminator (e-1) [n-butanol] was added, and the contents were reacted for one hour to obtain a solution of a polyurethane resin (U-1) for a polishing pad (the resin concentration: 25% by weight).

The polyurethane resin (U-1) had an ionic group concentration of 0.350 mol/kg, an Mn of 5,700, and a urethane group concentration of 2.7 mol/kg.

Next, the obtained polyurethane resin (U-1) solution was applied to a polyester film to a thickness of 2 mm and coagulated by immersing the workpiece for 30 minutes in a 30% by weight aqueous solution of N,N-dimethylformamide adjusted to 35° C.

Then, the workpiece was washed with warm water at 60° C. for 30 minutes and with water at 25° C. for 20 minutes. Then, the workpiece was dried with hot air at 80° C. to obtain a polishing pad (Uα-1).

The resulting polishing pad (Uα-1) was evaluated by the evaluation method described below. Table 1 shows the results.

### Examples 2 to 11 and Comparative Examples 1 to 3

Solutions of polyurethane resins (U) for a polishing pad and polishing pads (Uα) were prepared as in Example 1, except for changing the raw materials and weights (g) to those shown in Table 1.

### <Evaluation of Retention of Polishing Slurry>

The polishing pad (Uα) was cut into a size of 2 cm×2 cm to obtain an evaluation sheet (A). Using a fully automatic contact angle meter DM700 (Kyowa Interface Science Co., Ltd.), 30 μL of aqueous colloidal silica slurry [silicon dioxide concentration: 30% by weight, particle size: 5 to 15 nm, pH: 9 to 10] was dropped onto the evaluation sheet (A) at a temperature of 25° C., and the sliding angle of the droplet was measured. The retention of the polishing slurry was rated ⊚ (excellent) when the sliding angle was 35 degrees or more, ∘ (Good) when the sliding angle was 34 to 32 degrees, Δ (Fair) when the sliding angle was 31 to 29 degrees, and x (Poor) when the sliding angle was 28 degrees or less. Table 1 shows the results.

### <Evaluation of Durability>

The polishing pad (Uα) was punched into a No. 3 dumbbell shape to obtain an evaluation sheet (B). Next, the evaluation sheet (B) was heated in a constant temperature and humidity chamber at a temperature of 50° C. and a humidity of 60% for 20 hours to obtain an evaluation sheet (C).

Using an autograph (Shimadzu Corporation), the obtained evaluation sheets (B) and (C) were each stretched at a speed of 500 mm/min under conditions of a temperature of 25° C. and a humidity of 50%, and the tensile strength (unit: MPa) was determined from the maximum stress and the cross-sectional area.

The percentage of reduction in tensile strength before and after the constant temperature and humidity test was calculated using the following formula (1). The durability was rated ∘ when the percentage of reduction was lower than 6.0%, A when the percentage of reduction was 6.0% or higher and lower than 8.0%, and x when the percentage of reduction was 8.0% or higher. Table 1 shows the results.

100×{1−(C1)/(B1)} (unit: %) (1)
B1: tensile strength of evaluation sheet (B) (unit: MPa)
C1: tensile strength of evaluation sheet (C) (unit: MPa)

TABLE 1

| | | | Example | | | | | | |
|---|---|---|---|---|---|---|---|---|---|
| | | | 1 | 2 | 3 | 4 | 5 | 6 | 7 |
| Polyurethane resin (U) | | | U-1 | U-2 | U-3 | U-4 | U-5 | U-6 | U-7 |
| Polishing pad (Uα) | | | Uα-1 | Uα-2 | Uα-3 | Uα-4 | Uα-5 | Uα-6 | Uα-7 |
| Active | Polyether | (a11-1) | — | — | — | — | 3203 | — | — |
| hydrogen | polyol (a11) | (a11-2) | — | — | — | — | — | — | 559 |
| atom- | Polyester | (a12-1) | 3328 | 3372 | 3394 | 3407 | — | — | 2770 |
| con- | polyol (a12) | (a13-1) | — | — | — | — | — | 3332 | — |
| taining | Polycarbonate | | | | | | | | |
| com- | polyol (a13) | | | | | | | | |
| ponent | Compound (c) | (c-1) | 287 | 143 | 72 | 29 | 143 | 287 | 287 |
| (A) | | (c-2) | — | — | — | — | — | — | — |
| | | (c-3) | — | — | — | — | — | — | — |
| | Chain | (d-1) | 284 | 356 | 392 | 413 | 204 | 280 | 269 |
| | extender (d) | | | | | | | | |
| | Reaction | (e-1) | 120 | 120 | 120 | 120 | 120 | 120 | 120 |
| | terminator | | | | | | | | |
| Polyisocyanate (b) | | (b-1) | 2101 | 2129 | 2143 | 2151 | 2450 | 2101 | 2115 |
| | | (b-2) | — | — | — | — | — | — | — |
| Solvent (s) | | (s-1) | 17880 | 17880 | 17880 | 17880 | 17880 | 17880 | 17880 |
| Antioxidant | | | 3.3 | 3.4 | 3.4 | 3.4 | 3.4 | 3.4 | 3.4 |
| (dibutylhydroxytoluene) | | | | | | | | | |
| Gelation inhibitor | | | 0.72 | 0.72 | 0.72 | 0.72 | 0.72 | 0.72 | 0.72 |
| (benzoyl chloride) | | | | | | | | | |
| Poly- | Ionic group | | 0.350 | 0.175 | 0.087 | 0.035 | 0.174 | 0.350 | 0.350 |
| urethane | concentration | | | | | | | | |
| resin (U) | (mol/kg) | | | | | | | | |
| | Mn | | 5700 | 5600 | 5600 | 5500 | 5400 | 5700 | 5600 |
| | Resin concentration | | 25 | 25 | 25 | 25 | 25 | 25 | 25 |
| | of solution | | | | | | | | |
| | (% by weight) | | | | | | | | |
| | Weight of | | 100 | 100 | 100 | 100 | 100 | 100 | 86 |
| | component (A′) | | | | | | | | |
| | based on | | | | | | | | |
| | component (A) | | | | | | | | |
| | (% by weight) | | | | | | | | |
| Eval- | Evaluation of | | ⊚ | ⊚ | ⊚ | ⊚ | ⊚ | ⊚ | ⊚ |
| uation | retention of | | | | | | | | |
| result | polishing slurry | | | | | | | | |
| | Sliding angle | | 38 | 37 | 36 | 35 | 37 | 35 | 35 |
| | (degrees) | | | | | | | | |
| | Evaluation | | ◯ | ◯ | ◯ | ◯ | ◯ | ◯ | ◯ |
| | of durability | | | | | | | | |
| | B1 (MPa) | | 75.0 | 74.8 | 71.6 | 68.5 | 65.5 | 89.9 | 73.3 |
| | C1 (MPa) | | 71.4 | 71.2 | 67.6 | 64.5 | 62.6 | 86.3 | 69.9 |
| | 100 × {1 − (C1)/ | | 4.8 | 4.8 | 5.3 | 5.8 | 4.4 | 4.0 | 4.6 |
| | (B1)} (%) | | | | | | | | |
| | | | Example | | | | Comparative Example | | |
| | | | 8 | 9 | 10 | 11 | 1 | 2 | 3 |
| Polyurethane resin (U) | | | U-8 | U-9 | U-10 | U-11 | Com- | Com- | Com- |
| | | | | | | | parative | parative | parative |
| | | | | | | | U-1 | R-2 | U-3 |
| Polishing pad (Uα) | | | Uα-8 | Uα-9 | Uα-10 | Uα-11 | Com- | Com- | Com- |
| | | | | | | | parative | parative | parative |
| | | | | | | | Uα-1 | Uα-2 | Uα-3 |
| Active | Polyether | (a11-1) | — | — | — | — | — | — | — |
| hydrogen | polyol (a11) | (a11-2) | — | — | — | 784 | — | 3018 | 1009 |
| atom- | Polyester | (a12-1) | 3258 | 3328 | 3457 | 2545 | 3416 | — | 2320 |
| con- | polyol (a12) | (a13-1) | — | — | — | — | — | — | — |
| taining | Polycarbonate | | | | | | | | |
| com- | polyol (a13) | | | | | | | | |
| ponent | Compound (c) | (c-1) | 287 | — | — | 287 | — | 143 | 287 |
| (A) | | (c-2) | — | 317 | — | — | — | — | — |
| | | (c-3) | — | — | 317 | — | — | — | — |
| | Chain | (d-1) | 278 | 278 | 289 | 263 | 428 | 356 | 257 |
| | extender (d) | | | | | | | | |
| | Reaction | (e-1) | 120 | 120 | 120 | 120 | 120 | 120 | 120 |
| | terminator | | | | | | | | |

| | | | | | | | | |
|---|---|---|---|---|---|---|---|---|
| Polyisocyanate (b) | (b-1) | — | 2077 | 1937 | 2121 | 2157 | 2483 | 2127 |
| | (b-2) | 2177 | — | — | — | — | — | — |
| Solvent (s) | (s-1) | 17880 | 17880 | 17880 | 17880 | 17880 | 17880 | 17880 |
| Antioxidant | | 3.4 | 3.4 | 3.4 | 3.4 | 3.4 | 3.0 | 3.4 |
| (dibutylhydroxytoluene) | | | | | | | | |
| Gelation inhibitor | | 0.72 | 0.72 | 0.72 | 0.72 | 0.72 | 0.72 | 0.72 |
| (benzoyl chloride) | | | | | | | | |

| | | | | | | | | |
|---|---|---|---|---|---|---|---|---|
| Poly- | Ionic group | 0.350 | 0.350 | 0.219 | 0.350 | 0 | 0.175 | 0.350 |
| urethane | concentration | | | | | | | |
| resin (U) | (mol/kg) | | | | | | | |
| | Mn | 5500 | 5700 | 5600 | 5600 | 5500 | 5400 | 5700 |
| | Resin concentration | 25 | 25 | 25 | 25 | 25 | 25 | 25 |
| | of solution | | | | | | | |
| | (% by weight) | | | | | | | |
| | Weight of | 100 | 100 | 100 | 80 | 100 | 17 | 75 |
| | component (A′) | | | | | | | |
| | based on | | | | | | | |
| | component (A) | | | | | | | |
| | (% by weight) | | | | | | | |
| Eval- | Evaluation of | ⊚ | ⊚ | ⊚ | ⊚ | Δ | X | Δ |
| uation | retention of | | | | | | | |
| result | polishing slurry | | | | | | | |
| | Sliding angle | 37 | 38 | 37 | 33 | 31 | 14 | 30 |
| | (degrees) | | | | | | | |
| | Evaluation | ◯ | ◯ | ◯ | ◯ | Δ | ◯ | ◯ |
| | of durability | | | | | | | |
| | B1 (MPa) | 60.3 | 74.2 | 72.2 | 73.1 | 65.3 | 65.0 | 72.2 |
| | C1 (MPa) | 57.3 | 70.6 | 68.7 | 69.7 | 61.2 | 62.2 | 68.9 |
| | 100 × {1 − (C1)/ | 5.0 | 4.9 | 4.9 | 4.7 | 6.3 | 4.4 | 4.6 |
| | (B1)} (%) | | | | | | | |

The details of the various raw materials listed in Table 1 are as follows.

(Polyether Polyol (a11))
(a11-1): polyethylene glycol (Mn: 600, HLB: 21.1), trade name: PEG-600, available from Sanyo Chemical Industries, Ltd.
(a11-2): polytetramethylene ether glycol (Mn: 1,000, HLB: 4.1), trade name: PTMG1000, available from Mitsubishi Chemical Corporation
   (Polyester Polyol (a12))
(a12-1): polyethylene adipate diol (Mn: 2,000, HLB: 8.3), trade name: SANESTER 2620, available from Sanyo Chemical Industries, Ltd.
   (Polycarbonate Polyol (a13))
(a13-1): poly(tetramethylene/hexamethylene) carbonate diol (the molar ratio of the raw material diols is 1,6-hexanediol:1,4-butanediol=1:9, Mn: 2000, HLB: 8.5)

### (Polyisocyanate (b))

(b-1): 4,4′-diphenylmethane diisocyanate, trade name: Millionate MT, available from Tosoh Corporation
(b-2): 4,4′-methylenebiscyclohexyl diisocyanate, trade name: Desmodur W, available from Sumika Covestro Urethane Co., Ltd.

### (Compound (c))

(c-1): dimethylolpropionic acid (HLB: 43.8)
(c-2): 2,2-dimethylolbutanoic acid (HLB: 35.0)
(c-3): 3-(2,3-dihydroxypropoxy)-1-propanesulfonic acid (HLB: 65.5)

### (Chain Extender (d))

(d-1): ethylene glycol (HLB: 50.0)

### (Reaction Terminator (e))

(e-1): n-butanol (HLB: 12.5)

### (Solvent(s))

(s-1): N,N-dimethylformamide

### (Antioxidant)

Dibutylhydroxytoluene

### (Gelation Inhibitor)

Benzoyl chloride

The results in Table 1 demonstrate that the polishing pad (Uα) containing the polyurethane resin (U) for a polishing pad of the present invention is excellent in durability and excellent in retention of the polishing slurry. It is thus considered that the polishing pad (Uα) reduces scratches on a workpiece to be polished.

### INDUSTRIAL APPLICABILITY

The polyurethane resin (U) for a polishing pad and the polishing pad (Uα) of the present invention are suitable for various polishing applications, in particular, chemical mechanical polishing (CMP) applications.

1. A polyurethane resin (U) for a polishing pad, comprising, as constituent monomers:
at least one polyol (a) selected from the group consisting of a polyether polyol (a11), a polyester polyol (a12), and a polycarbonate polyol (a13);
a polyisocyanate (b); and
a compound (c) having an ionic group and two active hydrogen atoms,
the polyurethane resin (U) for a polishing pad containing, among constituent components thereof, an active hydrogen atom-containing component (A′) having an HLB of 8.0 or higher in an amount of 80 to 100% by weight based on a weight of an active hydrogen atom-containing component (A).

2. The polyurethane resin (U) for a polishing pad according to claim 1,
wherein the polyurethane resin (U) has an ionic group concentration of 0.020 to 0.500 mol/kg.

3. A polishing pad (Uα) comprising the polyurethane resin (U) for a polishing pad according to claim 1.
